(19) United States
(12) Patent Application Publication
(10) Pub. No.: US 2025/0089360 A1
(43) Pub. Date: Mar. 13, 2025

(54) SEMICONDUCTOR DEVICE WITH BOTTOM DIELECTRIC ISOLATOR AND MANUFACTURING METHOD THEREOF

(71) Applicant: TAIWAN SEMICONDUCTOR MANUFACTURING COMPANY, LTD., Hsinchu (TW)

(72) Inventors: Hao-Ming LIEN, Hsinchu City (TW); Wei-Yen WOON, Taoyuan City (TW); Hung-Kun LO, New Taipei City (TW)

(73) Assignee: TAIWAN SEMICONDUCTOR MANUFACTURING COMPANY, LTD., Hsinchu (TW)

(21) Appl. No.: 18/465,748

(22) Filed: Sep. 12, 2023

(51) Int. Cl. H01L 27/12

(52) U.S. Cl. CPC H10D 86/0214; H10D 86/0221; H10D 86/441; H10D 86/60; H10D 86/411

(57) ABSTRACT

A method includes forming a fin structure over a bottom dielectric isolator and a substrate. The fin structure includes a bottom channel layer, a sacrificial layer over the bottom channel layer, and a top channel layer over the sacrificial layer. A dummy gate is formed across the fin structure. Portions of the fin structure not covered by the gate structure are removed to expose a top surface of the bottom dielectric isolator. First source/drain epitaxial structures are epitaxially grown over the bottom dielectric isolator and are connected to the bottom channel layer. Second source/drain epitaxial structures are epitaxially grown over the first source/drain epitaxial structures and are connected to the top channel layer. The dummy gate and the sacrificial layer are replaced with a gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process can increase production efficiency and lower associated costs. Such scaling down has also increased the complexity of processing and manufacturing ICs and, for these advancements to be realized, similar developments in IC processing and manufacturing are desired. As the semiconductor industry further progresses in pursuit of higher device density, challenges from both fabrication and design issues have led to stacked device structure configurations, such as complementary field effect transistors (C-FET).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13C illustrate perspective views and cross-sectional views of intermediate stages in the formation of an integrated circuit structure (or a semiconductor device) in accordance with some embodiments of the present disclosure.

FIGS. 14-21C illustrate perspective views and cross-sectional views of intermediate stages in the formation of an integrated circuit structure (or a semiconductor device) in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

As used herein, the term “etch selectivity” refers to the ratio of the etch rates of two different materials under the same etching conditions. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). As used herein, the term “low-k” refers to a low dielectric constant. In the field of semiconductor device structures and manufacturing processes, low-k refers to a dielectric constant that is less than the dielectric constant of SiO₂ (e.g., less than 3.9). As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The nanostructure transistor (e.g., gate all around (GAA) transistor) structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit structures and methods of forming the same. More particularly, some embodiments of the present disclosure are related to complementary field-effect transistor (CFET) devices including a bottom dielectric isolator under source/drain epitaxial structures and a gate structure of a bottom nanostructure FET to prevent current leakage issues.

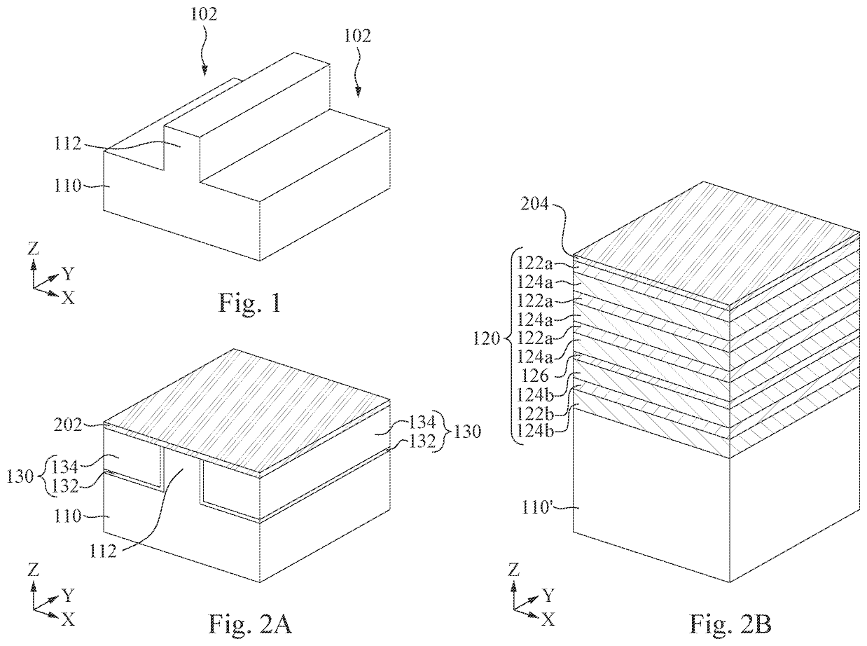

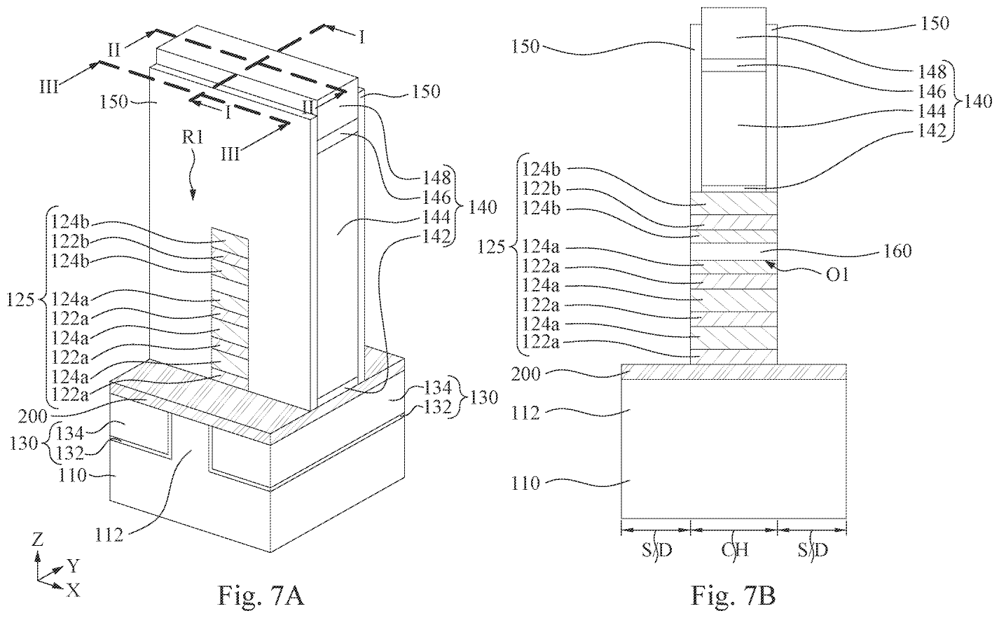

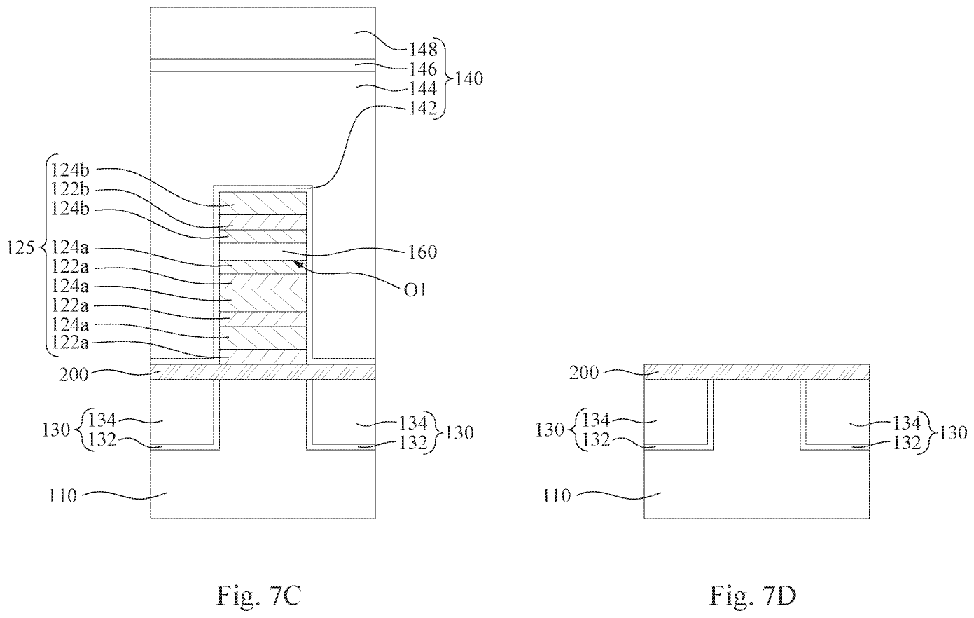

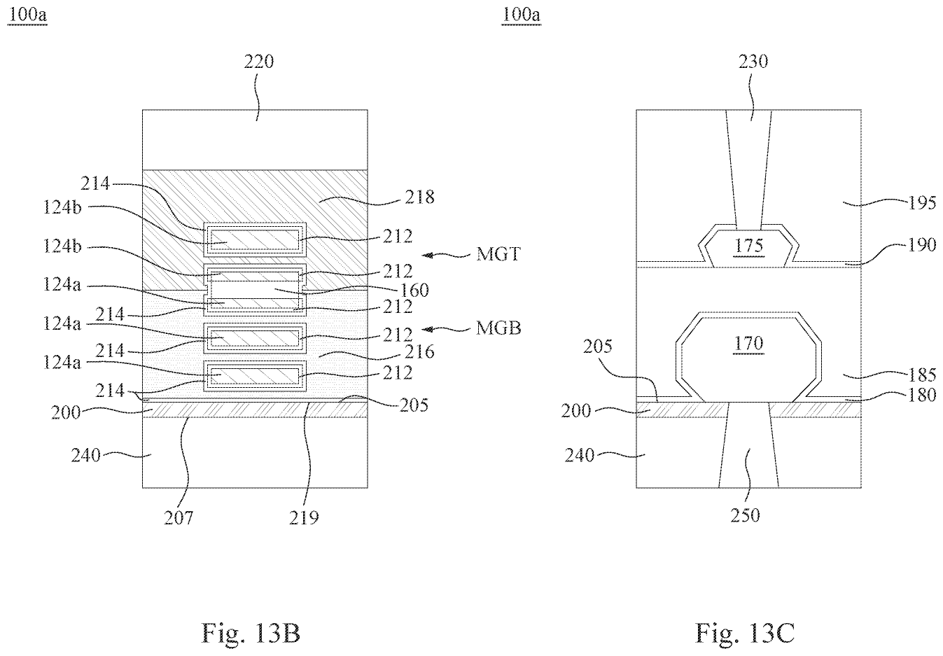

FIGS. 1-13C illustrate perspective views and cross-sectional views of intermediate stages in the formation of an integrated circuit structure (or a semiconductor device) 100a in accordance with some embodiments of the present disclosure. In some embodiments, the integrated circuit structures 100a in FIGS. 13A-13C are CFET devices. In addition to the integrated circuit structure 100a, FIGS. 1-7A depict X-axis, Y-axis, and Z-axis directions. FIGS. 7B, 8A, 9A, 10A, 11A, 12A, and 13A are cross-sectional views of some embodiments of the integrated circuit structure 100a at intermediate stages along a first cut (e.g., cut I-I in FIG. 7A). FIGS. 7C, 8B, 9B, 10B, 11B, 12B, and 13B are cross-sectional views of some embodiments of the integrated circuit structure 100a at intermediate stages along a second cut (e.g., cut II-II in FIG. 7A). FIGS. 7D, 8C, 9C, 10C, 11C, 12C, and 13C are cross-sectional views of some embodiments of the integrated circuit structure 100a at intermediate stages along a third cut (e.g., cut III-III in FIG. 7A). The formed devices include a p-type transistor (such as a p-type GAA FET) and an n-type transistor (such as an n-type GAA FET) in accordance with some exemplary embodiments. Throughout the various views and illustrative embodiments, like reference numbers are used to designate like elements. It is understood that additional operations can be provided before, during, and after the processes shown by FIGS. 1-13C, and some of the operations described below can be replaced or eliminated, for additional embodiments of the method. The order of the operations/processes may be interchangeable.

Reference is made to FIG. 1. A substrate 110 is provided. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. Subsequently, the substrate 110 is patterned to form a fin portion 112 defined by trenches 102.

Reference is made to FIG. 2A. Next, isolation structures 130 are formed in the trenches 102 (see FIG. 1) to surround the fin portion 112. The isolation structures 130 may include a liner layer 132. The liner layer 132 may be formed of a thermal oxide formed through a thermal oxidation of a surface layer of the substrate 110. The liner oxide may also be a deposited oxide layer or a nitride layer formed using, for example, Atomic Layer Deposition (ALD), High-Density Plasma Chemical Vapor Deposition (HDPCVD), or Chemical Vapor Deposition (CVD). The isolation structures 130 may also include a dielectric material 134 (e.g., silicon oxide) over the liner layer 132, and the dielectric material may be formed using flowable chemical vapor deposition (FCVD), spin-on coating, or the like. The isolation structures 130 are then planarized, such that the top surface of the fin portion 112 is exposed.

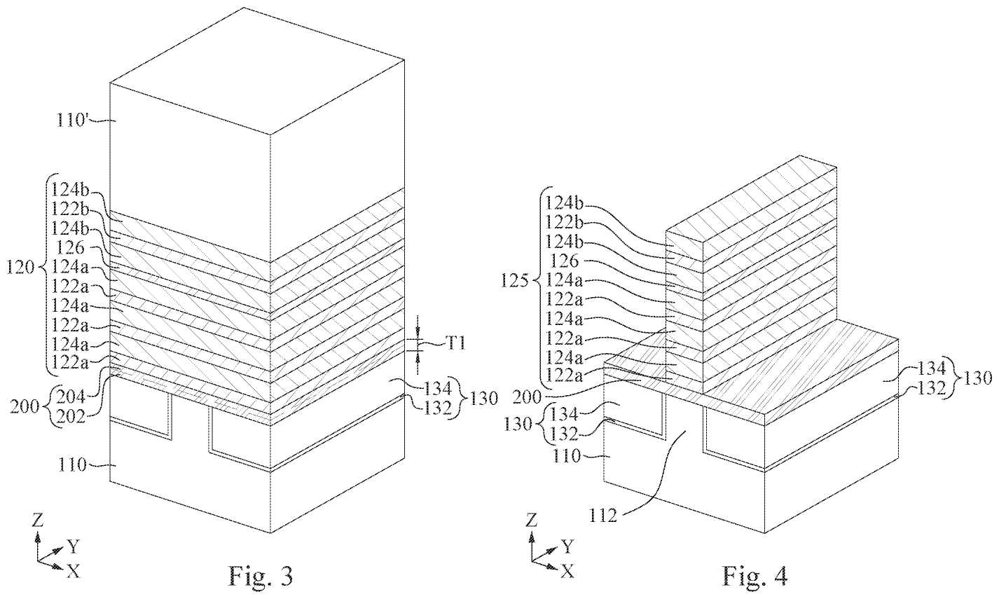

Subsequently, a first bonding layer (or a first dielectric layer) 202 is formed over the fin portion 112 and the isolation structures 130. The first bonding layer 202 may be deposited by any suitable process, such as PVD, CVD, ALD, or the like, and the first bonding layer 202 may facilitate the bonding of an epitaxial stack in subsequent processes (see FIG. 3). The first bonding layer 202 may include an insulating material that is suitable for a subsequent dielectric-to-dielectric bonding process. Example materials for the first bonding layer 202 include silicon oxide (e.g., SiO₂), silicon nitride, silicon oxynitride, silicon carbonitride, silicon oxycarbonitride, or the like.

Reference is made to FIG. 2B. An epitaxial stack 120 is formed over another substrate 110′. In some embodiments, the substrate 110′ may include silicon (Si). Alternatively, the substrate 110′ may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110′ may include a semiconductor-on-insulator (SOI) structure such as a buried dielectric layer. Also alternatively, the substrate 110′ may include a buried dielectric layer such as a buried oxide (BOX) layer, such as that formed by a method referred to as separation by implantation of oxygen (SIMOX) technology, wafer bonding, SEG, or another appropriate method.

The epitaxial stack 120 includes epitaxial layers 122a and 122b of a first composition interposed by epitaxial layers 124a and 124b of a second composition arranged in a stacking direction (Z-axis in this case). The epitaxial stack 120 further includes an epitaxial layer 126 of a third composition and between the bottommost epitaxial layer 124a and the topmost epitaxial layer 124b. The first, second, and third compositions are different. In some embodiments, the epitaxial layers 122a, 122b, and 126 are SiGe and the epitaxial layers 124a and 124b are silicon (Si). Further, the germanium concentration of the epitaxial layer 126 is higher than the germanium concentration of the epitaxial layer 122a and 122b. However, other embodiments are possible including those that provide for a first composition, a second composition, and a third composition having different etch selectivity.

The epitaxial layers 124a and 124b or portions thereof may form nanostructure channel(s) of the nanostructure transistors. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the epitaxial layers 124a and 124b to define a channel or channels of a device is further discussed below.

In FIG. 2B, the epitaxial layers 124b are disposed below the epitaxial layers 124a. However, after the bonding process as shown in FIG. 3, the epitaxial layers 124b will be disposed over the epitaxial layers 124a. It is noted that two layers of the epitaxial layers 124b and three layers of the epitaxial layers 124a are arranged as illustrated in FIG. 2B, which is for illustrative purposes only and not intended to be limiting beyond what is specifically recited in the claims. It can be appreciated that any number of epitaxial layers can be formed in the epitaxial stack 120; the number of layers depending on the desired number of channels regions for the transistor. In some embodiments, the number of each of the epitaxial layers 124a and 124b is between 1 and 10.

The epitaxial layers 122a are interposed by the epitaxial layers 124a, the epitaxial layers 122b are interposed by the epitaxial layers 124b, and the epitaxial layer 126 is between the epitaxial layers 124a and 124b. In some embodiments, the epitaxial layer 126 has a thickness less than the thicknesses of the epitaxial layers 122a, 122b, 124a, and 124b.

As described in more detail below, the epitaxial layers 124a and 124b may serve as channel region(s) for a subsequently-formed semiconductor device and the thickness is chosen based on device performance considerations. The epitaxial layers 122a and 122b in channel region(s) may eventually be removed and serve to define a vertical distance between adjacent channel region(s) for a subsequently-formed multi-gate device and the thickness is chosen based on device performance considerations. Accordingly, the epitaxial layers 122a and 122b may also be referred to as sacrificial layers, and epitaxial layers 124a and 124b may also be referred to as channel layers.

By way of example, epitaxial growth of the layers of the epitaxial stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124a and 124b include the same material as the substrate 110 and/or 110′. In some embodiments, the epitaxial layers 122a, 122b, 124a, 124b, and 126 include a different material than the substrate 110 and/or 110′. As stated above, in at least some examples, the epitaxial layers 122a, 122b, and 126 include an epitaxially grown silicon germanium (SiGe) layer and the epitaxial layers 124a and 124b include an epitaxially grown silicon (Si) layer. Alternatively, in some embodiments, either of the epitaxial layers 122a, 122b, 124a, 124b, and 126 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the epitaxial layers 122a, 122b, 124a, 124b, and 126 may be chosen based on providing differing oxidation and/or etching selectivity properties.

A second bonding layer (or a second dielectric layer) 204 is formed over the epitaxial stack 120. The second bonding layer 204 may be deposited by any suitable process, such as PVD, CVD, ALD, or the like. The second bonding layer 204 may include an insulating material that is suitable for a subsequent dielectric-to-dielectric bonding process. Example materials for the second bonding layer 204 include silicon oxide (e.g., SiO₂), silicon nitride, silicon oxynitride, silicon carbonitride, silicon oxycarbonitride, or the like. The second bonding layer 204 may have a same or different thickness than the first bonding layer 202.

Reference is made to FIG. 3. The structure in FIG. 2A and the structure in FIG. 2B are bonded at the surfaces on which the first and second bonding layers 202 and 204 are formed using a suitable technique, such as dielectric-to-dielectric bonding, or the like. The first and second bonding layers 202 and 204 are combined and become a bottom dielectric isolator 200 bonding the substrate 110, the isolation structures 130, and the epitaxial stack 120. The bottom dielectric isolator 200 is disposed between and bridges the substrate 110, the isolation structures 130, and the epitaxial stack 120. In some embodiments, the bottom dielectric isolator 200 has a thickness T1 in a range from about 50 angstroms to about 70 angstroms.

The dielectric-to-dielectric bonding process may include applying a surface treatment to one or more of the first bonding layer 202 and the second bonding layer 204. The surface treatment may include a plasma treatment. The plasma treatment may be performed in a vacuum environment. After the plasma treatment, the surface treatment may further include a cleaning process (e.g., a rinse with deionized water or the like) that may be applied to one or more of the bottom dielectric isolator 200. An annealing process may be then applied by, for example, heating the substrate 110, the isolation structure 130, and the epitaxial stack 120. The annealing process drives or triggers the formation of covalent bonds between the first bonding layer 202 and the second bonding layer 204. Other bonding processes, such as ambient bonding, vacuum bonding, or the like may be used in other embodiments.

Reference is made to FIG. 4. The substrate 110′ in FIG. 3 is removed, such that the top surface of the epitaxial layer 124b is exposed. Subsequently, the epitaxial stack 120 (see FIG. 3) is patterned to form at least one fin structure 125 extending from the bottom dielectric isolator 200. In various embodiments, the fin structure 125 includes portions of each of the epitaxial layers of the epitaxial stack 120 including the epitaxial layers 122a, 122b, 124a, 124b, and 126. After the patterning process, the top surface of the bottom dielectric isolator 200 is exposed. The bottom dielectric isolator 200 covers the isolation structures 130.

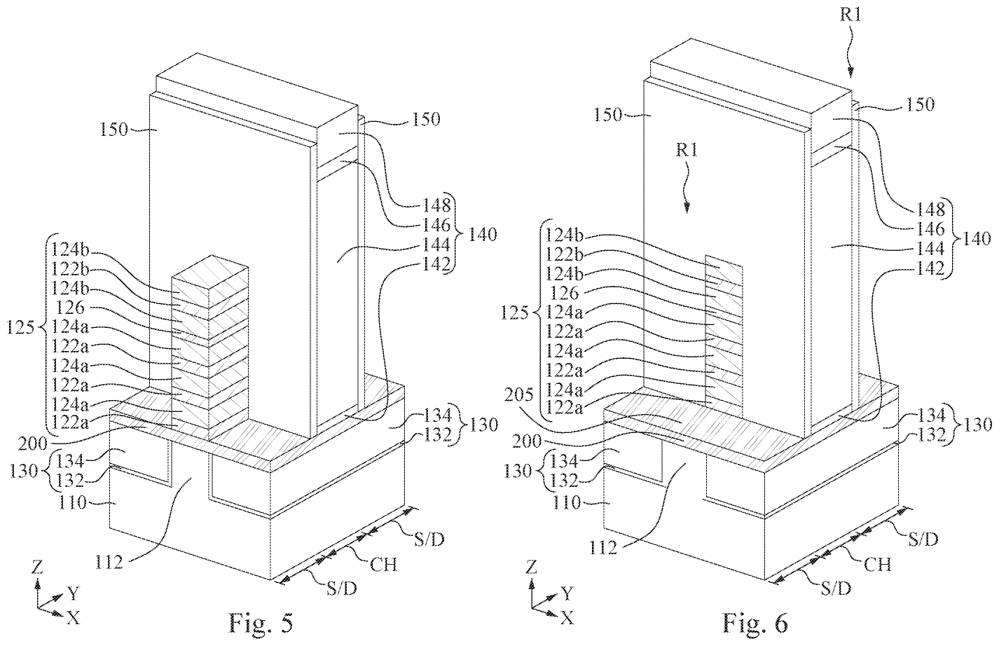

Reference is made to FIG. 5. At least one dummy gate structure 140 is formed over the substrate 110 and across the fin structure 125. The portion of the fin structure 125 underlying the dummy gate structure 140 may be referred to as the channel region CH. The dummy gate structure 140 may also define source/drain regions S/D of the fin structure 125, for example, the regions of the fin structure 125 adjacent and on opposite sides of the channel region CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, a dummy gate structure 140 including a dummy gate dielectric layer 142, a dummy gate electrode layer 144 and a hard mask (e.g., a nitride layer 146 and an oxide layer 148) is formed.

After formation of the dummy gate structure 140 is completed, gate spacers 150 are formed on opposite sidewalls of the dummy gate structure 140. For example, a spacer material layer is deposited on the substrate 110. The spacer material layer may be a conformal layer that is subsequently etched back to form gate sidewall spacers. In the illustrated embodiment, a spacer material layer is disposed conformally on top and sidewalls of the dummy gate structure 140. The spacer material layer may include a dielectric material such as silicon oxide, silicon nitride, silicon carbide, silicon oxynitride, SiCN films, silicon oxycarbide, SiOCN films, and/or combinations thereof. By way of example, the spacer material layer may be formed by depositing a dielectric material over the dummy gate structure 140 using suitable deposition processes. An anisotropic etching process is then performed on the deposited spacer material layer to expose portions of the fin structure 125 not covered by the dummy gate structure 140 (e.g., over the source/drain regions S/D of the fin structure 125). Portions of the spacer material layer directly above the dummy gate structure 140 may be completely removed by this anisotropic etching process. Portions of the spacer material layer on sidewalls of the dummy gate structure 140 may remain, forming gate sidewall spacers, which are denoted as the gate spacers 150, for the sake of simplicity.

Reference is made to FIG. 6. Exposed portions of the fin structure 125 that extend laterally beyond the gate spacers 150 (e.g., in source/drain regions S/D of the fin structure 125) are etched by using, for example, an anisotropic etching process that uses the dummy gate structure 140 and the gate spacers 150 as an etch mask, resulting in recesses R1 into the fin structure 125. After the anisotropic etching, end surfaces of the epitaxial layers 122a, 122b, 124a, 124b, 126 and respective outermost sidewalls of the gate spacers 150 are substantially coterminous, due to the anisotropic etching. In addition, the top surface 205 of the bottom dielectric isolator 200 is exposed on the bottom of the recesses R1. In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like.

Reference is made to FIGS. 7A-7D, where FIG. 7B is a cross-sectional view taken along line I-I of FIG. 7A, FIG. 7C is a cross-sectional view taken along line II-II of FIG. 7A, and FIG. 7D is a cross-sectional view taken along line III-III of FIG. 7A. The epitaxial layer 126 (see FIG. 6) is removed, resulting in an opening O1 between the topmost epitaxial layers 124a and the bottommost epitaxial layers 124b. In some embodiments, during the selective etching processes, some portions of the epitaxial layers 124a and 124b are also etched. As such, a vertical thickness of the opening O1 is greater than the thickness of the epitaxial layer 126. Subsequently, a middle dielectric isolator 160 is filled in the opening O1, such that the middle dielectric isolator 160 is between the epitaxial layers 124a and 124b. For example, a dielectric material layer is formed to fill the opening O1. The dielectric material layer may be a low-k dielectric material, such as SiO₂, SiN, SiC, SiON, SiCN, or SiOCN, and may be formed by a suitable deposition method, such as ALD. In some embodiments, the dielectric material layer is intrinsic or un-doped with impurities. The dielectric material layer can be formed using CVD, including LPCVD and PECVD, PVD, ALD, or other suitable processes.

After the deposition of the dielectric material layer, an anisotropic etching process may be performed to remove the dielectric material layer outside the opening O1, such that portions of the deposited dielectric material layer that fill the opening O1 are left. After the etching process, the remaining portion of the deposited spacer material in the opening O1 is denoted as the middle dielectric isolator 160, for the sake of simplicity. The middle dielectric isolator 160 serves to isolate the epitaxial layers 124a from the epitaxial layers 124b.

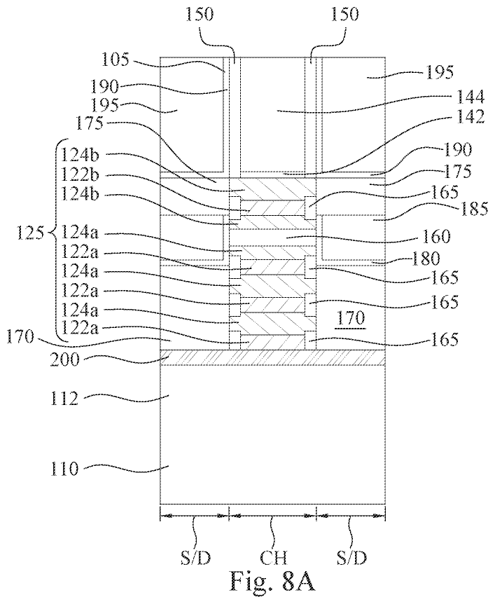

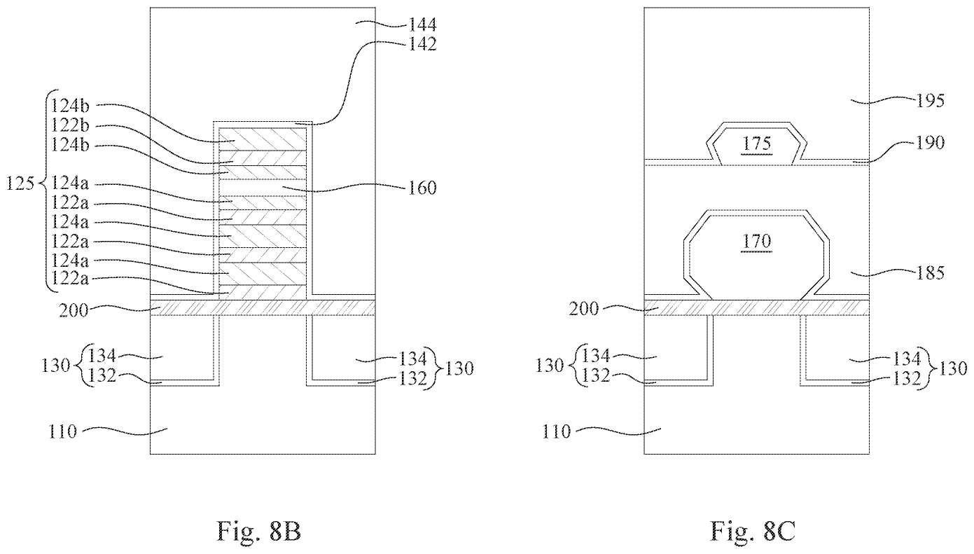

Reference is made to FIGS. 8A-8C. The epitaxial layers 122a and 122b are then laterally or horizontally recessed by using suitable etch techniques, resulting in lateral recesses each vertically between corresponding epitaxial layers 124a and 124b. These operations may be performed by using selective etching processes. By way of example and not limitation, the epitaxial layers 122a and 122b are SiGe and the epitaxial layers 124a and 124b are silicon allowing for the selective etching of the epitaxial layers 122a and 122b. In some embodiments, the selective dry etching etches SiGe at a faster etch rate than it etches Si. As a result, the epitaxial layers 124a and 124b laterally extend past opposite end surfaces of the epitaxial layers 122a and 122b. In some embodiments, during the selective etching processes, some portions of the epitaxial layers 124a and 124b are also etched as shown in FIG. 8A.

Subsequently, inner dielectric spacers 165 are filled in the recesses, respectively. For example, spacer material layers are formed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

After the deposition of the spacer material layer, an anisotropic etching process may be performed to trim the deposited spacer material layer, such that portions of the deposited spacer material layer that fill the recesses are left. After the trimming process, the remaining portions of the deposited spacer material in the recesses are denoted as inner dielectric spacers 165, for the sake of simplicity. The inner dielectric spacers 165 serve to isolate metal gates from source/drain epitaxial structures formed in subsequent processing.

Subsequently, first source/drain epitaxial structures 170, a first contact etch stop layer (CESL) 180, a first interlayer dielectric (ILD) layer 185, second source/drain epitaxial structures 175, a second CESL 190, and a second ILD layer 195 are sequentially formed over the source/drain regions S/D of the fin structure 125. The first source/drain epitaxial structures 170 are on opposite sides and connected to the epitaxial layers 124a and spaced apart from the epitaxial layers 124b. The second source/drain epitaxial structures 175 are on opposite sides and connected to the epitaxial layers 124b and spaced apart from the epitaxial layers 124a. The first source/drain epitaxial structures 170 and second source/drain epitaxial structures 175 may be formed by performing an epitaxial growth process that provides an epitaxial material on the fin structure 125. In some embodiments, the lattice constants of the first source/drain epitaxial structures 170 are different from the lattice constant of the epitaxial layers 124a, so that the epitaxial layers 124a can be strained or stressed by the first source/drain epitaxial structures 170 to improve carrier mobility of the semiconductor device and enhance the device performance. Similarly, the lattice constants of the second source/drain epitaxial structures 175 are different from the lattice constant of the epitaxial layers 124b. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the epitaxial layers 124a or 124b.

In some embodiments, the first source/drain epitaxial structures 170 and the second source/drain epitaxial structures 175 may include Ge, Si, GaAs, AlGaAs, SiGe, GaAsP, SiP, or other suitable material. The first source/drain epitaxial structures 170 and the second source/drain epitaxial structures 175 may be in-situ doped during the epitaxial process by introducing doping species including: p-type dopants, such as boron or BF₂; n-type dopants, such as phosphorus or arsenic; and/or other suitable dopants including combinations thereof. If the first source/drain epitaxial structures 170 and/or the second source/drain epitaxial structures 175 are not in-situ doped, an implantation process (i.e., a junction implant process) is performed to dope the first source/drain epitaxial structures 170 and/or second source/drain epitaxial structures 175. In some exemplary embodiments, the first source/drain epitaxial structures 170 are in an n-type include SiP and/or SiC. In some exemplary embodiments, the second source/drain epitaxial structures 175 are in a p-type include SiGeB and/or GeSnB.

The first CESL 180 is formed on the substrate 110 and covers the first source/drain epitaxial structures 170. The second CESL 190 covers the second source/drain epitaxial structures 175. In some examples, the first CESL 180 and the second CESL 190 include a silicon nitride layer, silicon oxide layer, a silicon oxynitride layer, and/or other suitable materials. The first CESL 180 and the second CESL 190 may be formed by plasma-enhanced chemical vapor deposition (PECVD) process and/or other suitable deposition or oxidation processes.

The first ILD layer 185 is formed over the first CESL 180, and the second ILD layer 195 is formed over the second CESL 190. In some embodiments, the first ILD layer 185 and the second ILD layer 195 include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the first CESL 180. The first ILD layer 185 and the second ILD layer 195 may be deposited by a PECVD process or other suitable deposition technique.

In some examples, after depositing the second ILD layer 195, a planarization process may be performed to remove excessive materials of the second ILD layer 195. For example, a planarization process includes a chemical mechanical planarization (CMP) process which removes portions of the second ILD layer 195 and the second CESL 190 overlying the dummy gate structures 140 and planarizes a top surface of the integrated circuit structure 100a. In some embodiments, the CMP process also removes hard mask layers 146 and 148 (as shown in FIGS. 7A-7C) and exposes the dummy gate electrode layer 144.

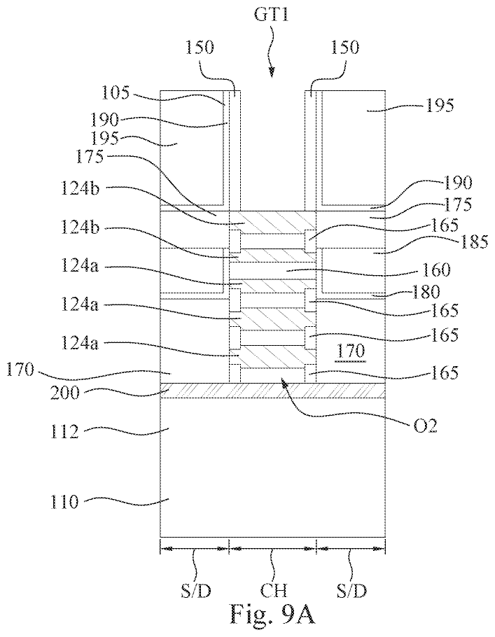

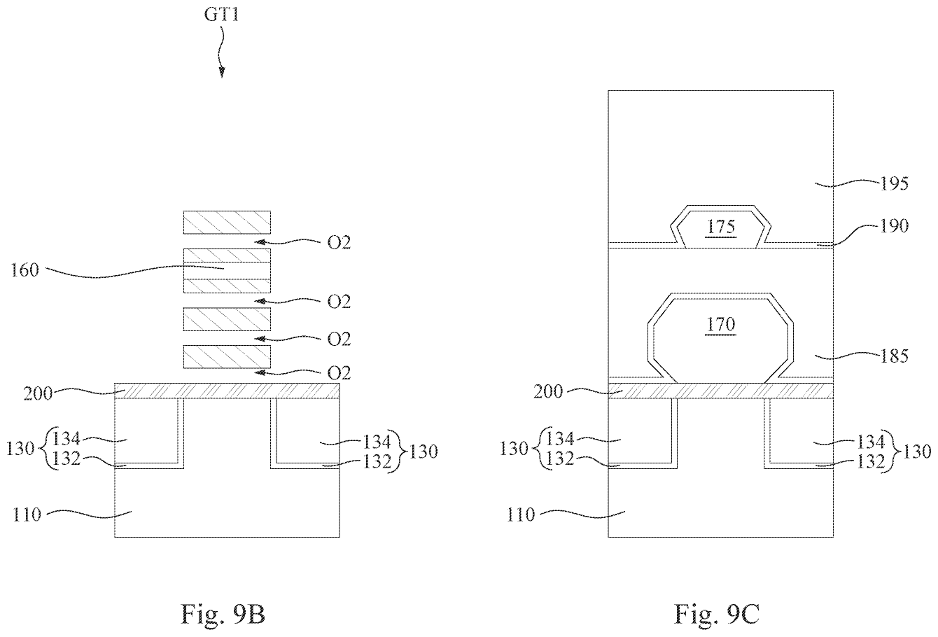

Reference is made to FIG. 9A-9C. Thereafter, a gate replacement process is performed. Specifically, the dummy gate electrode layer 144 and the dummy gate dielectric layer 142 are removed first, and then the epitaxial layers (i.e., sacrificial layers) 122a and 122b are removed. In some embodiments, the dummy gate electrode layer 144 is removed by using a selective etching process (e.g., selective dry etching, selective wet etching, or combinations thereof) that etches the materials in dummy gate electrode layer 144 at a faster etch rate than it etches other materials (e.g., the gate spacers 150 and/or the second ILD layer 195), thus resulting in a gate trench GT1 between the gate spacers 150, with the epitaxial layers 122a and 122b exposed in the gate trench GT1. Subsequently, the epitaxial layers 122a and 122b in the gate trench GT1 are removed by using another selective etching process that etches the epitaxial layers 122a and 122b at a faster etch rate than it etches the epitaxial layers 124a and 124b, thus forming openings O2 between neighboring epitaxial layers (i.e., channel layers) 124a and 124b. In this way, the epitaxial layers 124a and 124b become nanosheets suspended over the substrate 110. This operation is also called a channel release process. In some embodiments, the epitaxial layers 124a and 124b can be interchangeably referred to as nanostructure (nanowires, nanoslabs and nanorings, nanosheet, etc., depending on their geometry). For example, in some other embodiments the epitaxial layers 124a and 124b may be trimmed to have a substantial rounded shape (i.e., cylindrical) due to the selective etching process for completely removing the epitaxial layers 124a and 124b. In that case, the resultant epitaxial layers 124a and 124b can be called nanowires.

In some embodiments, the epitaxial layers 122a and 122b are removed by using a selective dry etching process by using, for example, CF₄ as etching gases. In some embodiments, the epitaxial layers 122a and 122b are SiGe and the epitaxial layers 124a and 124b are silicon allowing for the selective removal of the epitaxial layers 122a and 122b. In some embodiments, during the selective etching processes, some portions of the epitaxial layers 124a and 124b are also etched. As such, vertical thicknesses of the openings O2 are greater than the thicknesses of the epitaxial layers 122a and 122b.

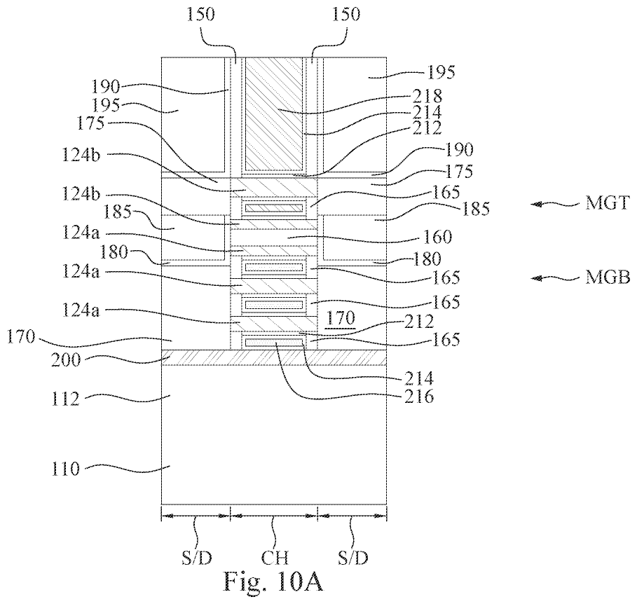

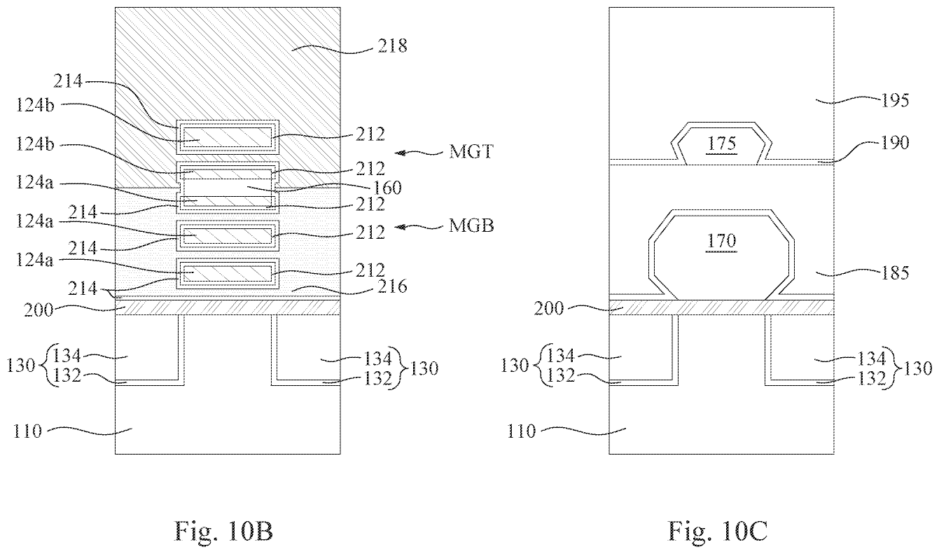

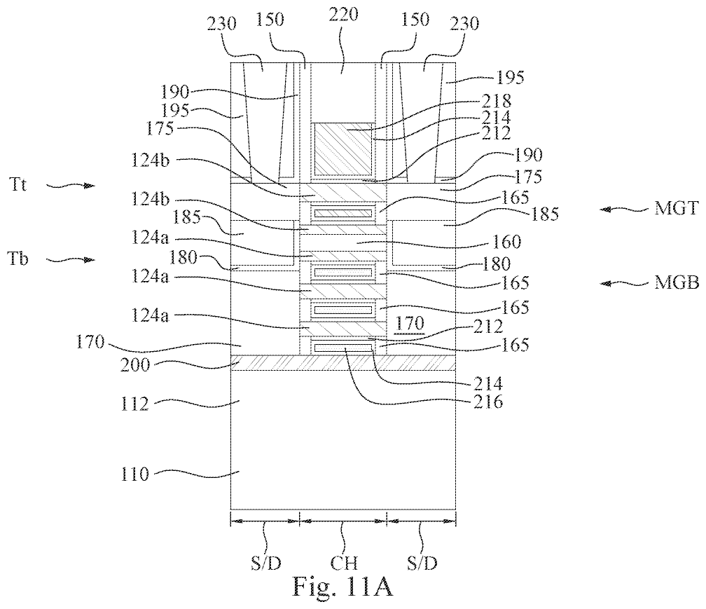

Reference is made to FIGS. 10A-10C. Interfacial layers 212 are formed around the epitaxial layers 124a and 124b. In some embodiments, the interfacial layer 212 may include a dielectric material such as silicon oxide (SiO₂), HfSiO, or silicon oxynitride (SiON). The interfacial layers 212 may be formed by chemical oxidation, thermal oxidation, atomic layer deposition (ALD), chemical vapor deposition (CVD), and/or other suitable method. In some embodiments, when the interfacial layers 212 are formed by oxidation, the interfacial layers 212 are grown on the surfaces of semiconductor materials, such as the epitaxial layers 124a and 124b.

Thereafter, high-k gate dielectric layers 214 are formed to cover the interfacial layers 212. High-k gate dielectrics include dielectric materials having a high dielectric constant, for example, greater than that of thermal silicon oxide (˜3.9). The high-k gate dielectric layer 214 of the gate dielectric layer may include hafnium oxide (HfO₂). Alternatively, the high-k gate dielectric layer 214 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k gate dielectric layers 214 may be formed by atomic layer deposition (ALD), chemical vapor deposition (CVD), and/or other suitable method.

Next, a work function metal layer 216 is deposited in the gate trench GT1 (see FIGS. 9A and 9B) and fills the gate trench GT1. The work function metal layer 216 may include work function metals to provide a suitable work function for the gate structure MGB. For a p-type FET, the work function metal layer 216 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The work function metal layer 216 may be formed by atomic layer deposition (ALD), chemical vapor deposition (CVD), and/or other suitable method. Subsequently, one or more CMP processes are performed to remove excessive gate materials.

After the formation of the work function metal layer 216, the work function metal layer 216 is etched back by using an etching process, and the top portions of the high-k gate dielectric layers 214 are exposed. Subsequently, another work function metal layer 218 is deposited in the gate trench GT1 and over the work function metal layer 216 and fill the gate trench GT1. For an n-type FET, the work function metal layer 218 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials.

Therefore, the interfacial layers 212, the high-k gate dielectric layers 214, and the work function metal layer 216 form a gate structure MGB, and the interfacial layers 212, the high-k gate dielectric layers 214, and the work function metal layer 218 form a gate structure MGT over the gate structure MGB.

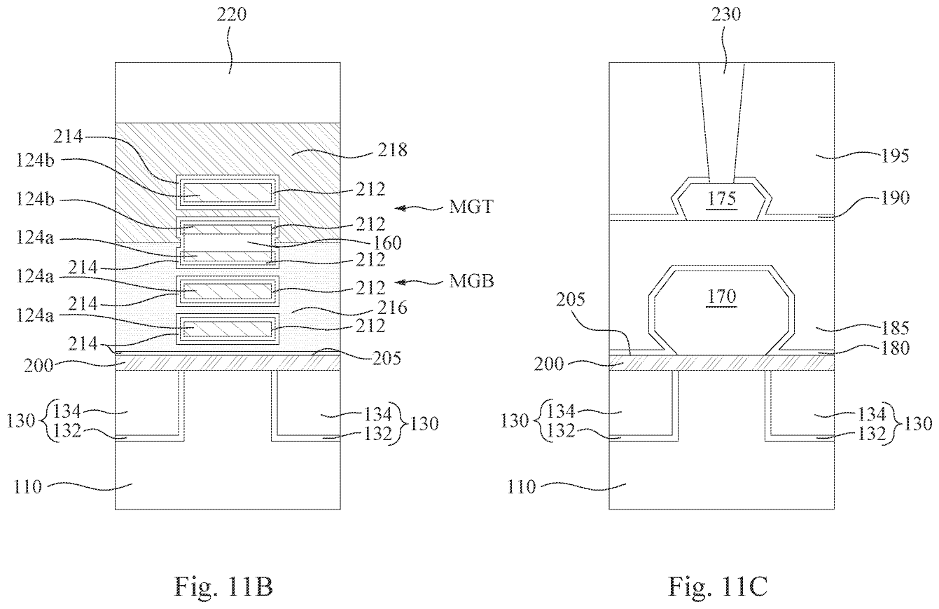

Reference is made to FIGS. 11A-11C. After the formation of the gate structures MGB and MGT as shown in FIGS. 10A and 10B, an etching back process is optionally performed to etch back the gate structure MGT, resulting in a recess over the etched-back gate structure MGT. In some embodiments, because the materials of the gate structures MGT have a different etch selectivity than the gate spacers 150, a selective etching process may be performed to etch back the gate structure MGT to lower the gate structure MGT. As a result, the top surface of the gate structure MGT may be at a lower level than the top surfaces of the gate spacers 150.

Subsequently, a dielectric cap layer is deposited over the substrate 110 until the recess is overfilled. The dielectric cap layer includes SiNₓ, AlₓOy, AlON, SiOₓC_{y}, SiCₓN_{y}, boron nitride (BN), boron carbonitride (BNC), combinations thereof or the like, and is formed by a suitable deposition technique such as CVD, plasma-enhanced CVD (PECVD), ALD, remote plasma ALD (RPALD), plasma-enhanced ALD (PEALD), combinations thereof or the like. A CMP process is then performed to remove the cap layer outside the recess, leaving portions of the dielectric cap layer in the recess to serve as a dielectric cap 220. The dielectric cap 220 is in direct contact with the gate structure MGT as shown in FIGS. 11A and 11B.

Next, openings are formed in the second ILD layer 195. The opening exposes the second source/drain epitaxial structures 175. Source/drain contacts 230 are then respectively formed in the openings. In some embodiments, prior to the formation of the source/drain contacts 230, metal alloy layers are formed in the openings and on the exposed portions of the second source/drain epitaxial structures 175. Each of the source/drain contacts 230 is connected to the second source/drain epitaxial structure 175. Formation of the source/drain contacts 230 includes depositing one or more conductive (e.g., metal) materials overfilling the openings and then performing a CMP process to remove excessive metal materials outside the openings.

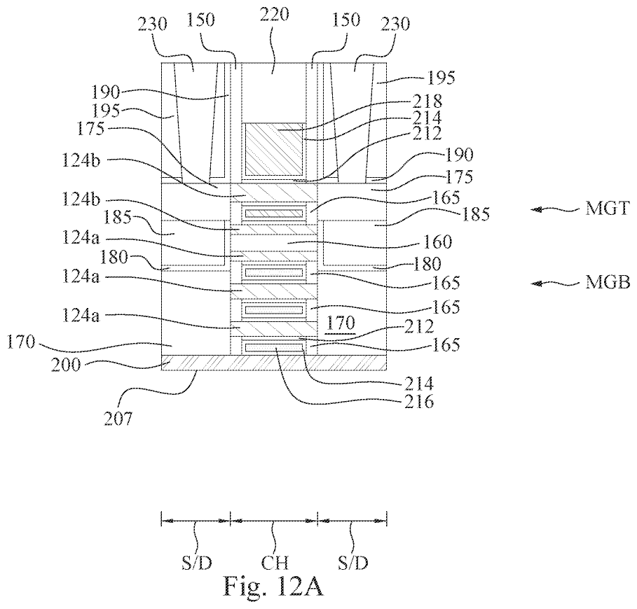

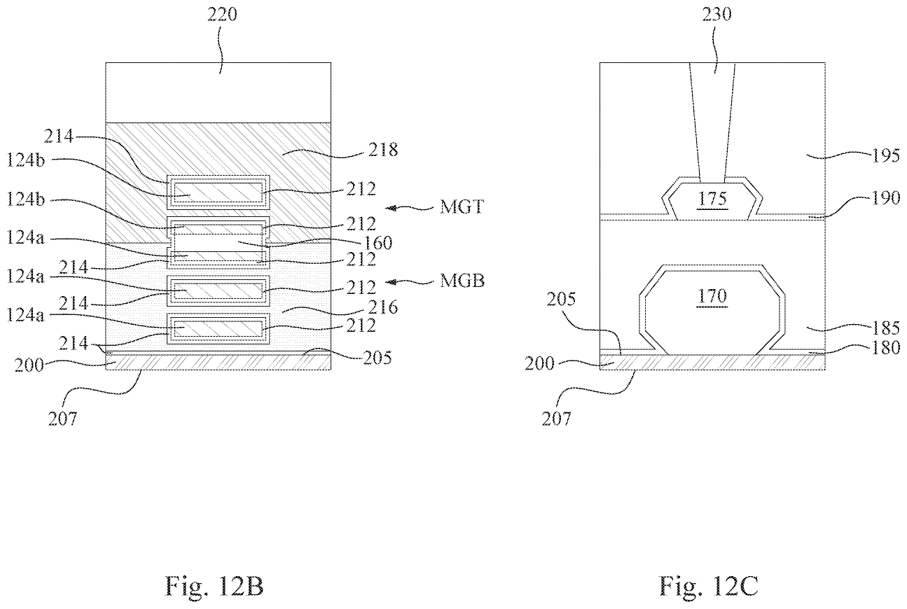

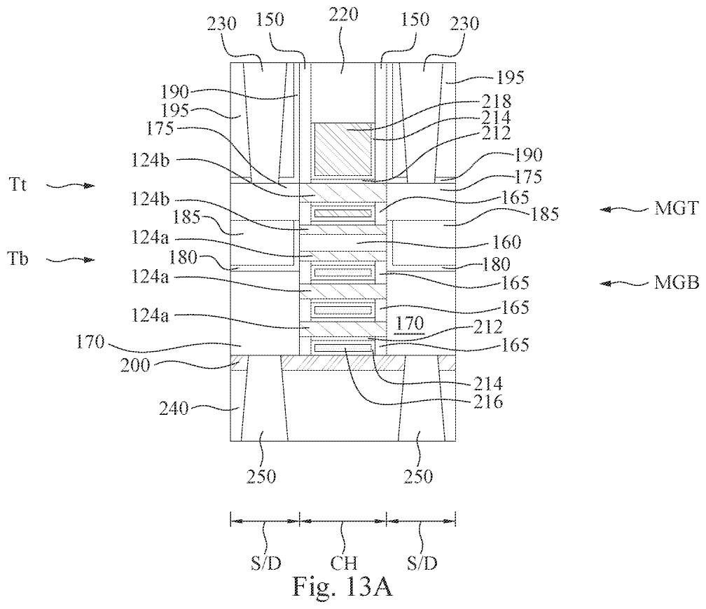

Reference is made to FIGS. 12A-12C. Subsequently, the substrate 110 and the isolation structures 130 (as shown in FIGS. 11A-11C) are removed, such that the bottom surface 207 of the bottom dielectric isolator 200 is exposed. In some embodiments, a chemical mechanical planarization (CMP) process is performed to remove the substrate 110 and the isolation structures 130. It is noted that the bottom dielectric isolator 200 can be used as an etch stop layer during this removal process, such that the gate structure MGB and the first source/drain epitaxial structures 170 are not damaged when the substrate 110 and the isolation structures 130 are removed.

Reference is made to FIGS. 13A-13C. A dielectric isolation layer 240 is then deposited to cover the backside of the bottom dielectric isolator 200. In some embodiments, the dielectric isolation layer 240 is made of materials the same as or similar to that of the first ILD layer 185. Next, backside vias 250 are formed in the dielectric isolation layer 240 and the bottom dielectric isolator 200 to be electrically connected to the first source/drain epitaxial structures 170. In some embodiments, openings are formed in the dielectric isolation layer 240 and the bottom dielectric isolator 200. The openings expose the first source/drain epitaxial structures 170. The backside vias 250 are then respectively formed in the openings. In some embodiments, prior to the formation of the backside vias 250, metal alloy layers are formed in the openings and on the exposed portions of the first source/drain epitaxial structures 170. Each of the backside vias 250 is connected to the first source/drain epitaxial structure 170. Formation of the backside vias 250 includes depositing one or more conductive (e.g., metal) materials overfilling the openings and then performing a CMP process to remove excessive metal materials outside the openings.

As such, the semiconductor device 100a is formed. As shown in FIGS. 13A-13C, the semiconductor device 100a includes a bottom dielectric isolator 200, a bottom (nanostructure) transistor Tb, and a top (nanostructure) transistor Tt. The top transistor Tt and the bottom transistor Tb form a CFET. The bottom transistor Tb is over the bottom dielectric isolator 200, and the top transistor Tt is over the bottom transistor Tb. The bottom transistor Tb includes the (bottom) channel layers 124a, the first source/drain epitaxial structures 170 on opposite sides of the channel layers 124a and connected to the channel layers 124a, and the gate structure MGB wrapping around the channel layers 124a. The top transistor Tt includes the (top) channel layers 124b, the second source/drain epitaxial structures 175 on opposite sides of the channel layers 124b and connected to the channel layers 124b, and the gate structure MGT wrapping around the channel layers 124b. The bottom transistor Tb is a P-type transistor, and the top transistor Tt is an N-type transistor, or vice versa.

In FIG. 13A, the bottom dielectric isolator 200 is in contact with the first source/drain epitaxial structures 170 and the gate structure MGB. Therefore, the first source/drain epitaxial structures 170 and the gate structure MGB are directly over the bottom dielectric isolator 200. The bottom dielectric isolator 200 is configured to prevent the electrical current from leaking between the first source/drain epitaxial structures 170 and the gate structure MGB. The bottom dielectric isolator 200 is further in contact with the inner dielectric spacers 165 as shown in FIG. 13A. Further, the bottom dielectric isolator 200 is in contact with and surrounds the backside vias 250. In FIG. 13B, the bottom dielectric isolator 200 is covered by the high-k gate dielectric layers 214 of the gate structure MGB. Specifically, the high-k gate dielectric layer 214 is in contact with a top surface 205 of the bottom dielectric isolator 200. Further, in some embodiments, a bottom surface 207 of the bottom dielectric isolator 200 is lower than a bottom surface 219 of the gate structure MGB. In FIG. 13C, the CESL 180 is in contact with the top surface 205 of the bottom dielectric isolator 200.

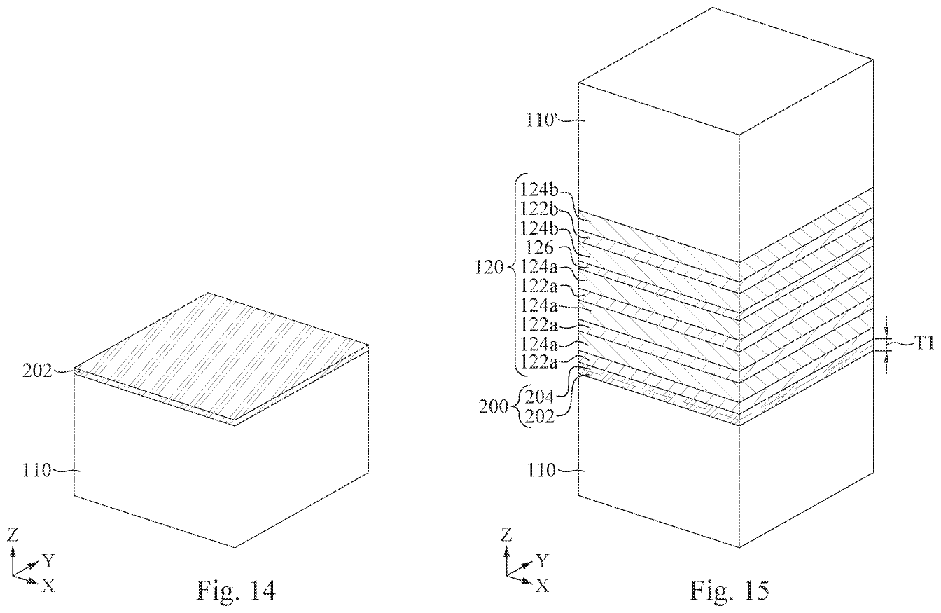

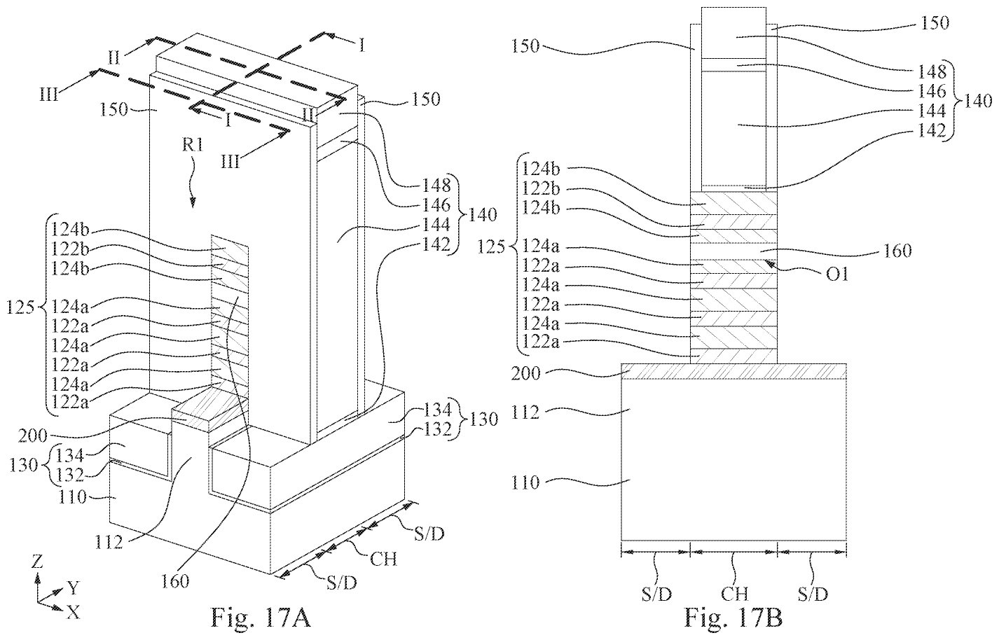

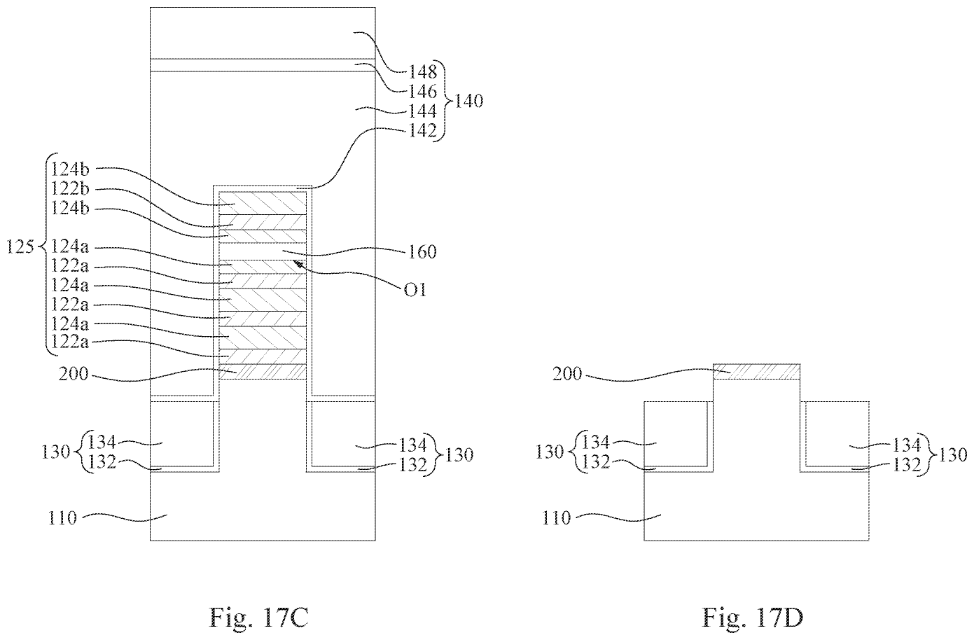

FIGS. 14-21C illustrate perspective views and cross-sectional views of intermediate stages in the formation of an integrated circuit structure (or a semiconductor device) 100b in accordance with some embodiments of the present disclosure. In some embodiments, the semiconductor devices in FIGS. 14-21C are CFET devices. In addition to the integrated circuit structure 100b, FIGS. 14-17A depict X-axis, Y-axis, and Z-axis directions. FIGS. 17B, 18A, 19A, 20A, and 21A are cross-sectional views of some embodiments of the integrated circuit structure 100b at intermediate stages along a first cut (e.g., cut I-I in FIG. 17A). FIGS. 17C, 18B, 19B, 20B, and 21B are cross-sectional views of some embodiments of the integrated circuit structure 100b at intermediate stages along a second cut (e.g., cut II-II in FIG. 17A). FIGS. 17D, 18C, 19C, 20C, and 21C are cross-sectional views of some embodiments of the integrated circuit structure 100b at intermediate stages along a third cut (e.g., cut III-III in FIG. 17A). The formed devices include a p-type transistor (such as a p-type GAA FET) and an n-type transistor (such as an n-type GAA FET) in accordance with some exemplary embodiments. Throughout the various views and illustrative embodiments, like reference numbers are used to designate like elements. It is understood that additional operations can be provided before, during, and after the processes shown by FIGS. 14-21C, and some of the operations described below can be replaced or eliminated, for additional embodiments of the method. The order of the operations/processes may be interchangeable.

Reference is made to FIG. 14. A substrate 110 is provided. The substrate 110 in FIG. 14 is the same as or similar to the substrate 110 in FIG. 1A. Subsequently, a first bonding layer (or a first dielectric layer) 202 is formed over the substrate 110. The first bonding layer 202 in FIG. 14 is the same as or similar to the first bonding layer 202 in FIG. 1A.

Reference is made to FIG. 15. The structure in FIG. 14 and the structure in FIG. 2B are bonded at the surfaces on which the first and second bonding layers 202 and 204 are formed. The first and second bonding layers 202 and 204 are combined and become a bottom dielectric isolator 200 bonding the substrate 110 and the epitaxial stack 120. The bottom dielectric isolator 200 is disposed between and bridges the substrate 110 and the epitaxial stack 120. In some embodiments, the bottom dielectric isolator 200 has a thickness T1 in a range from about 50 angstroms to about 70 angstroms.

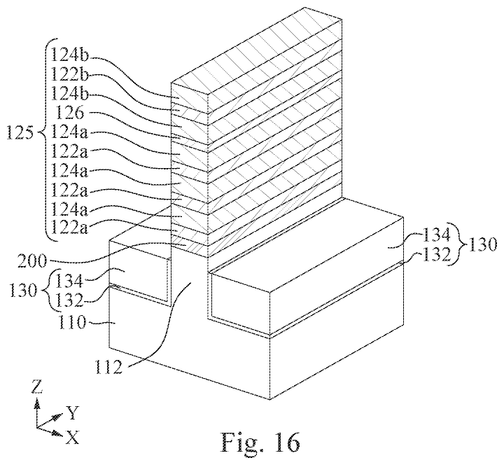

Reference is made to FIG. 16. The substrate 110′ in FIG. 15 is removed, such that the top surface of the epitaxial layer 124b is exposed. Subsequently, the epitaxial stack 120 (see FIG. 15) is patterned to form at least one fin structure 125 extending from the bottom dielectric isolator 200. In various embodiments, the fin structure 125 includes portions of each of the epitaxial layers of the epitaxial stack 120 including epitaxial layers 122a, 122b, 124a, 124b, and 126. Further, the bottom dielectric isolator 200 and the substrate 110 in FIG. 15 are also patterned to form a fin portion 112 of the substrate 110 and an bottom dielectric isolator 200 between the fin portion 112 and the fin structure 125.

The epitaxial stack 120, the bottom dielectric isolator 200, and the substrate 110 may be patterned using suitable processes including double-patterning or multi-patterning processes. For example, a hard mask (HM) layer is formed over the epitaxial stack 120 prior to forming the fin structure 125. The fin structure 125 may subsequently be fabricated using suitable processes including photolithography and etch processes. The photolithography process may include forming a photoresist layer (not shown) over the HM layer, exposing the photoresist to a pattern, performing post-exposure bake processes, and developing the resist to form a patterned mask including the resist. The patterned mask may then be used to protect regions of the substrate 110, and layers formed thereupon, while an etch process forms trenches in unprotected regions through the HM layer, through the epitaxial stack 120, the bottom dielectric isolator 200, and into the substrate 110, thereby leaving the fin structure 125, the bottom dielectric isolator 200, and the fin portion 112. The trenches may be etched using a dry etch (e.g., reactive ion etching), a wet etch, and/or combination thereof.

Next, isolation structures 130 are formed to surround the fin portion 112, the bottom dielectric isolator 200, and the fin structure 125. The isolation structures 130 may include a liner layer 132. The liner layer 132 may be formed of a thermal oxide formed through a thermal oxidation of a surface layer of the substrate 110. The liner oxide may also be a deposited oxide layer or a nitride layer formed using, for example, Atomic Layer Deposition (ALD), High-Density Plasma Chemical Vapor Deposition (HDPCVD), or Chemical Vapor Deposition (CVD). The isolation structures 130 may also include a dielectric material 134 (e.g., silicon oxide) over the liner layer 132, and the dielectric material may be formed using flowable chemical vapor deposition (FCVD), spin-on coating, or the like.

The isolation structures 130 are then planarized, such that the HM layer is removed, and the top surface of the fin structure 125 is exposed. Subsequently, the isolation structures 130 are recessed, so that the fin structure 125, the bottom dielectric isolator 200, and the top of the fin portion 112 protrude higher than the top surfaces of the neighboring isolation structures 130. The etching may be performed using a dry etching process. In accordance with alternative embodiments of the present disclosure, the recessing of the isolation structures 130 is performed using a wet etch process.

Reference is made to FIGS. 17A-17D, where FIG. 17B is a cross-sectional view taken along line I-I of FIG. 17A, FIG. 17C is a cross-sectional view taken along line II-II of FIG. 17A, and FIG. 17D is a cross-sectional view taken along line III-III of FIG. 17A. After the formation of the fin structure 125, the structure of FIG. 16 undergoes the processes similar to the processes shown in FIGS. 5-7D to form at least one dummy gate structures 140, gate spacers 150, and a middle dielectric isolator 160. Materials, configurations, dimensions, processes and/or operations regarding the dummy gate structures 140 in FIG. 17A are similar to or the same as the dummy gate structures 140 of FIG. 5. Materials, configurations, dimensions, processes and/or operations regarding the gate spacers 150 in FIG. 17A are similar to or the same as the gate spacers 150 of FIG. 5. Materials, configurations, dimensions, processes and/or operations regarding the middle dielectric isolator 160 in FIG. 17A are similar to or the same as the middle dielectric isolator 160 of FIGS. 7A-7C.

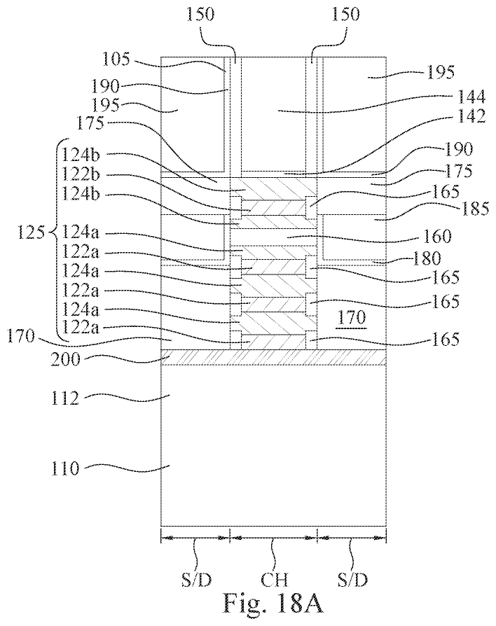

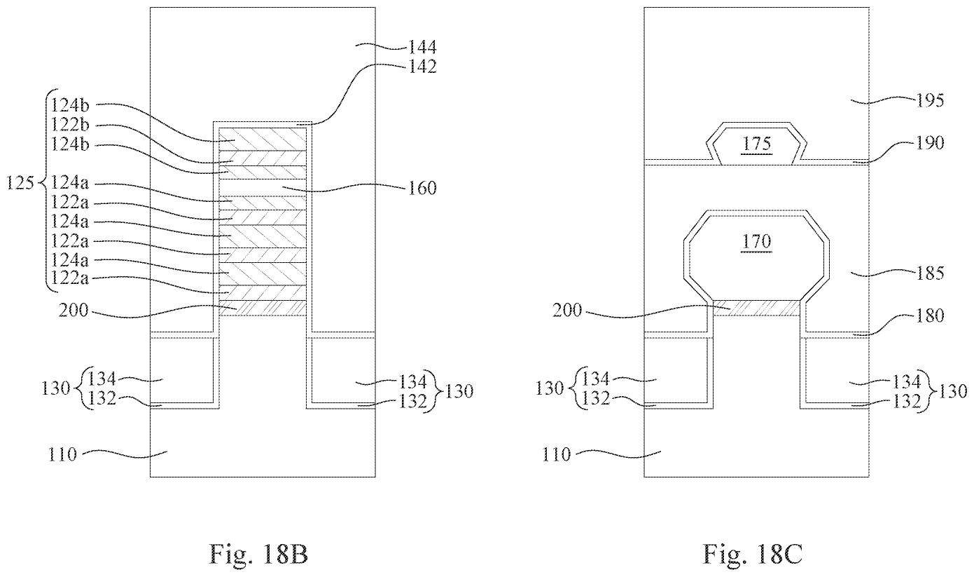

Reference is made to FIGS. 18A-18C. After the formation of the middle dielectric isolator 160, the structure of FIGS. 17A-17D undergoes the processes similar to processes shown in FIGS. 8A-8C. Specifically, recesses are formed in the epitaxial layers 122a and 122b, and inner dielectric spacers 165 are filled in the recesses. Materials, configurations, dimensions, processes and/or operations regarding the inner dielectric spacers 165 in FIG. 18A are similar to or the same as the inner dielectric spacers 165 of FIG. 8A.

Subsequently, first source/drain epitaxial structures 170 are formed over the bottom dielectric isolator 200 and connected to the epitaxial layers 124a. Materials, configurations, dimensions, processes and/or operations regarding the first source/drain epitaxial structures 170 in FIGS. 18A and 18C are similar to or the same as the first source/drain epitaxial structures 170 of FIGS. 8A and 8C.

Next, a first CESL 180 and a first ILD layer 185 are formed over the first source/drain epitaxial structures 170. Materials, configurations, dimensions, processes and/or operations regarding the first CESL 180 in FIGS. 18A and 18C are similar to or the same as the first CESL 180 of FIGS. 8A and 8C. Materials, configurations, dimensions, processes and/or operations regarding the first ILD layer 185 in FIGS. 18A and 18C are similar to or the same as the first ILD layer 185 of FIGS. 8A and 8C.

Second source/drain epitaxial structures 175 are formed over the source/drain regions S/D of the fin structure 125 and connected to the epitaxial layers 124b. Materials, configurations, dimensions, processes and/or operations regarding the second source/drain epitaxial structures 175 in FIGS. 18A and 18C are similar to or the same as the second source/drain epitaxial structures 175 of FIGS. 8A and 8C.

Next, a second CESL 190 and a second ILD layer 195 are formed over the second source/drain epitaxial structures 175, and a planarization process is performed to remove the hard mask layers 146 and 148 (see FIG. 17A-17C). Materials, configurations, dimensions, processes and/or operations regarding the second CESL 190 in FIGS. 18A and 18C are similar to or the same as the second CESL 190 of FIGS. 8A and 8C. Materials, configurations, dimensions, processes and/or operations regarding the second ILD layer 195 in FIGS. 18A and 18C are similar to or the same as the second ILD layer 195 of FIGS. 8A and 8C.

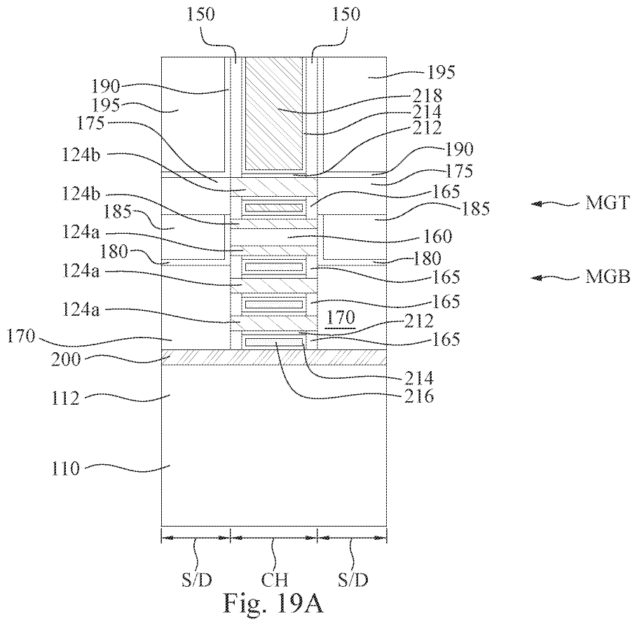

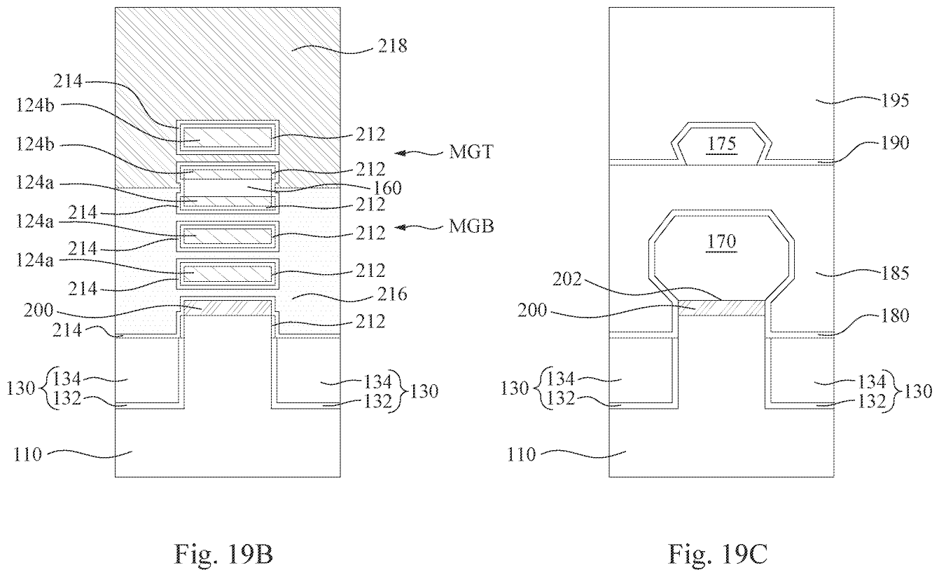

Reference is made to FIGS. 19A-19C. After the formation of the second CESL 190 and the second ILD layer 195, the structure of FIGS. 18A-18C undergoes the processes similar to processes shown in FIGS. 9A-10C. Specifically, the dummy gate electrode layer 144 and the dummy gate dielectric layer 142 are removed first, and then the epitaxial layers (i.e., sacrificial layers) 122a and 122b are removed. Processes and/or operations regarding the removal process in FIGS. 19A and 19B are similar to or the same as the removal process shown in FIGS. 9A and 9B.

Subsequently, gate structures MGB and MGT are formed. The gate structure MGB includes interfacial layers 212, high-k gate dielectric layers 214, and work function metal layer 216, and the gate structure MGT includes the interfacial layers 212, the high-k gate dielectric layers 214, and work function metal material 218. Materials, configurations, dimensions, processes and/or operations regarding the gate structures MGB and MGT in FIGS. 19A and 19B are similar to or the same as the gate structures MGB and MGT of FIGS. 10A and 10B.

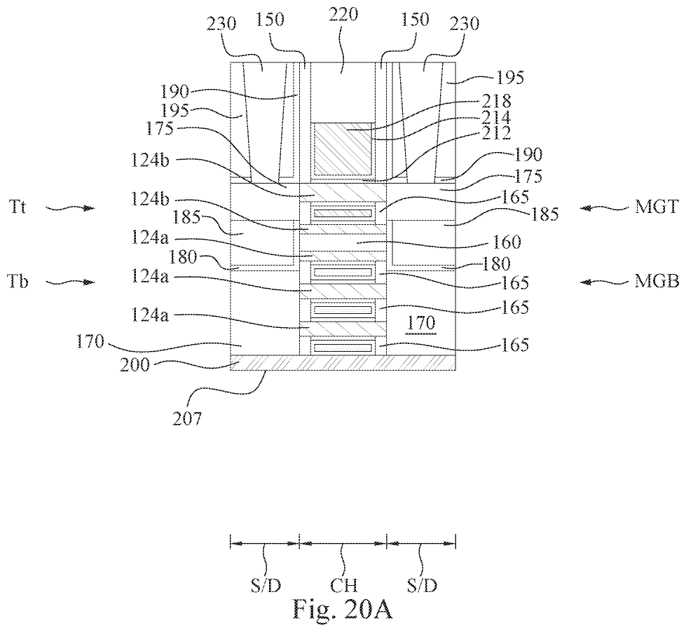

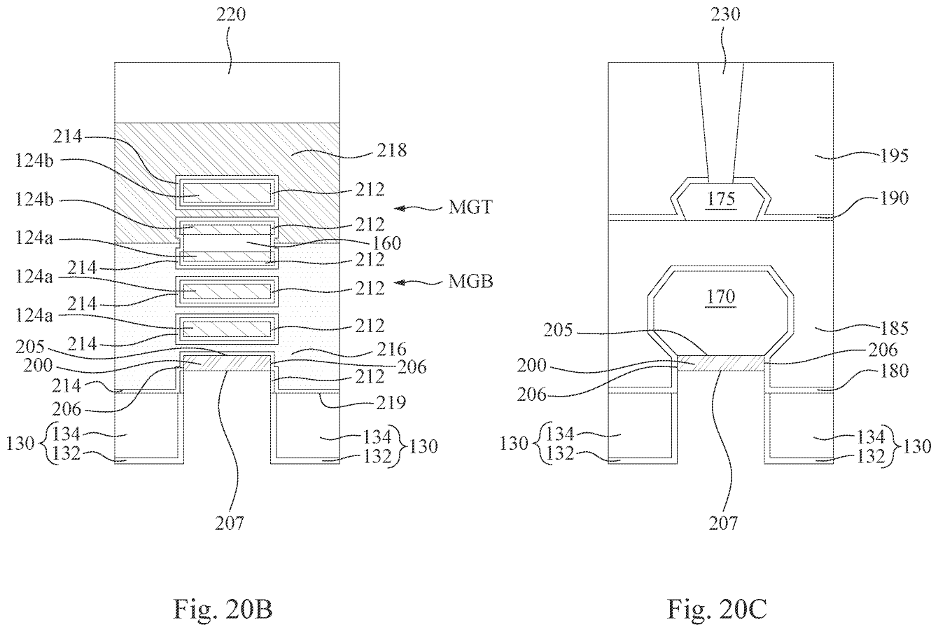

Reference is made to FIGS. 20A-20C. After the formation of the gate structures MGB and MGT, the structure of FIGS. 19A-19C undergoes the processes similar to processes shown in FIGS. 11A-12C. In some embodiments, an etching back process is optionally performed to etch back the gate structure MGT, resulting in a recess over the etched-back gate structure MGT. A dielectric cap 220 is formed over the gate structure MGT. Materials, configurations, dimensions, processes and/or operations regarding the dielectric cap 220 in FIGS. 20A and 20B are similar to or the same as the dielectric cap 220 of FIGS. 11A and 11B.

Source/drain contacts 230 are then formed in the second ILD layer 195. In some embodiments, prior to the formation of the source/drain contacts 230, metal alloy layers are formed on the exposed portions of the second source/drain epitaxial structures 175. Each of the source/drain contacts 230 is connected to the second source/drain epitaxial structure 175. Materials, configurations, dimensions, processes and/or operations regarding the source/drain contacts 230 in FIGS. 20A and 20C are similar to or the same as the source/drain contacts 230 and 235 of FIGS. 11A and 11C.

Subsequently, the substrate 110 (as shown in FIGS. 19A and 19B) is removed, such that the bottom surface 207 of the bottom dielectric isolator 200 is exposed. It is noted that the bottom dielectric isolator 200 can be used as an etch stop layer during this removal process, such that the gate structure MGB and the first source/drain epitaxial structures 170 are not damaged when the substrate 110 is removed. In some embodiments, a CMP process may be performed to thin the substrate 110 until backsides of the isolation structures 130 are exposed. Subsequently, the remaining portion of the substrate 110 between the isolation structures 130 is etched to expose the bottom dielectric isolator 200. It is noted that the bottom dielectric isolator 200 can be used as an etch stop layer during this removal process, such that the gate structure MGB and the first source/drain epitaxial structures 170 are not damaged when the substrate 110 is removed (or etched).

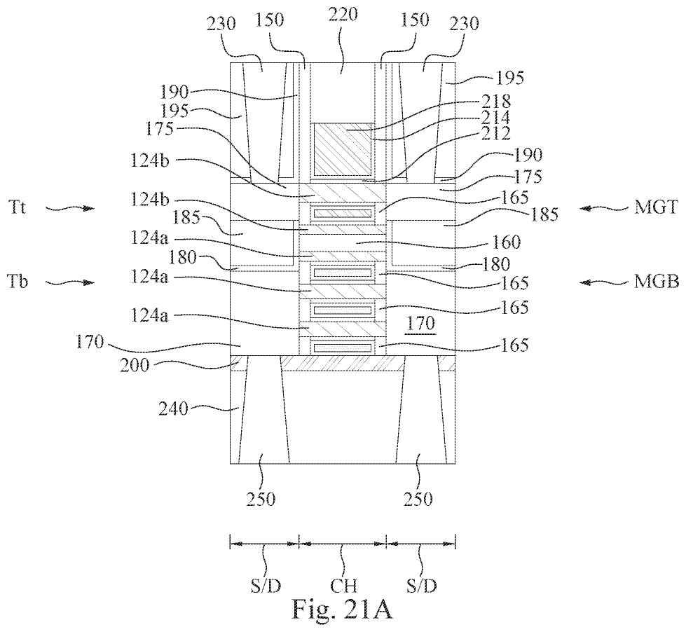

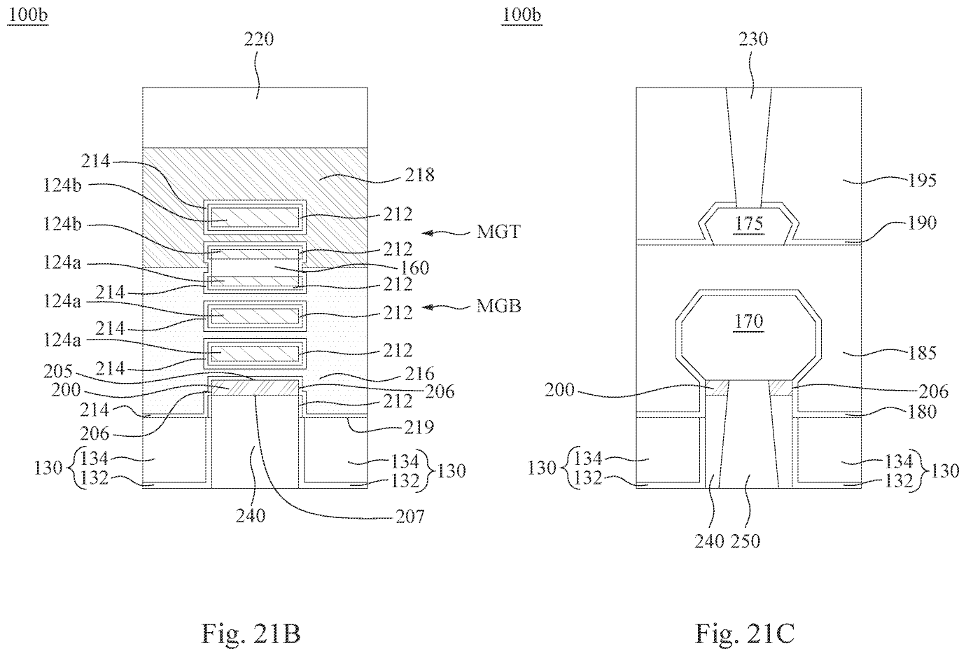

Reference is made to FIGS. 21A-21C. A dielectric isolation layer 240 is then deposited to cover the backside of the bottom dielectric isolator 200. Materials, configurations, dimensions, processes and/or operations regarding the dielectric isolation layer 240 in FIGS. 21A and 21C are similar to or the same as the dielectric isolation layer 240 of FIGS. 13A and 13C.

Next, backside vias 250 are formed in the dielectric isolation layer 240 and the bottom dielectric isolator 200 to be electrically connected to the first source/drain epitaxial structures 170. Materials, configurations, dimensions, processes and/or operations regarding the backside vias 250 in FIGS. 21A and 21C are similar to or the same as the backside vias 250 of FIGS. 13A and 13C.

As such, the semiconductor device 100b is formed. As shown in FIGS. 21A-21C, the semiconductor device 100b includes a bottom dielectric isolator 200, a bottom (nanostructure) transistor Tb, and a top (nanostructure) transistor Tt. The top transistor Tt and the bottom transistor Tb form a CFET. The bottom transistor Tb is over the bottom dielectric isolator 200, and the top transistor Tt is over the bottom transistor Tb. The bottom transistor Tb includes the (bottom) channel layers 124a, the first source/drain epitaxial structures 170 on opposite sides of the channel layers 124a and connected to the channel layers 124a, and the gate structure MGB wrapping around the channel layers 124a. The top transistor Tt includes the (top) channel layers 124b, the second source/drain epitaxial structures 175 on opposite sides of the channel layers 124b and connected to the channel layers 124b, and the gate structure MGT wrapping around the channel layers 124b. The bottom transistor Tb is a P-type transistor, and the top transistor Tt is an N-type transistor, or vice versa.

In FIG. 21A, the bottom dielectric isolator 200 is in contact with the first source/drain epitaxial structures 170 and the gate structure MGB. The bottom dielectric isolator 200 is configured to prevent the electrical current from leaking between the first source/drain epitaxial structures 170 and the gate structure MGB. The bottom dielectric isolator 200 is further in contact with the inner dielectric spacers 165 as shown in FIG. 21A. Further, the bottom dielectric isolator 200 is in contact with and surrounds the backside vias 250. In FIG. 21B, the bottom dielectric isolator 200 is covered by the high-k gate dielectric layers 214 of the gate structure MGB. Specifically, the high-k gate dielectric layer 214 is in contact with a top surface 205 and sidewalls 206 of the bottom dielectric isolator 200. Further, in some embodiments, a bottom surface 207 of the bottom dielectric isolator 200 may be higher than a bottom surface 219 of the gate structure MGB. In FIG. 21C, the CESL 180 covers the first source/drain epitaxial structures 170 and is in contact with the sidewalls 206 of the bottom dielectric isolator 200.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the bottom dielectric isolator below the bottom nanostructure device prevents the electrical current of the bottom source/drain epitaxial structures from leaking between the bottom source/drain epitaxial structures and the gate structure. Further, the bottom dielectric isolator can be an etch stop layer for substrate-removal process.

According to some embodiments, a method includes forming a fin structure over a bottom dielectric isolator and a substrate. The fin structure includes a bottom channel layer, a sacrificial layer over the bottom channel layer, and a top channel layer over the sacrificial layer. A dummy gate is formed across the fin structure. Portions of the fin structure not covered by the gate structure are removed to expose a top surface of the bottom dielectric isolator. First source/drain epitaxial structures are epitaxially grown over the bottom dielectric isolator and are connected to the bottom channel layer. Second source/drain epitaxial structures are epitaxially grown over the first source/drain epitaxial structures and are connected to the top channel layer. The dummy gate and the sacrificial layer are replaced with a gate structure.

According to some embodiments, a method includes forming a first dielectric layer over a substrate. A second dielectric layer is formed over an epitaxial stack. The second dielectric layer is bonded to the first dielectric layer to form a bottom dielectric isolator. The epitaxial stack is over the substrate and includes a first channel layer, a sacrificial layer, and a second channel layer from bottom to top. A complementary field-effect transistor (CFET) is formed over the substrate and the bottom dielectric isolator. The CFET includes the first channel layer and the second channel layer of the epitaxial stack.

According to some embodiments, a device includes a bottom dielectric isolator, a bottom nanostructure transistor, and a top nanostructure transistor. The bottom nanostructure transistor is over the bottom dielectric isolator and includes a first channel layer, a first gate structure, a first source/drain epitaxial structure, and a second source/drain epitaxial structure. The first gate structure wraps around the first channel layer and is in contact with the bottom dielectric isolator. The first source/drain epitaxial structure and the second source/drain epitaxial structure are connected to the first channel layer and directly over the bottom dielectric isolator. The top nanostructure transistor is over the bottom nanostructure transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a fin structure over a bottom dielectric isolator and a substrate, wherein the fin structure comprises a bottom channel layer, a sacrificial layer over the bottom channel layer, and a top channel layer over the sacrificial layer;
forming a dummy gate across the fin structure;
removing portions of the fin structure not covered by the dummy gate to expose a top surface of the bottom dielectric isolator;
epitaxially growing first source/drain epitaxial structures over the bottom dielectric isolator and connected to the bottom channel layer;
epitaxially growing second source/drain epitaxial structures over the first source/drain epitaxial structures and connected to the top channel layer; and
replacing the dummy gate and the sacrificial layer with a gate structure.

2. The method of claim 1, wherein epitaxially growing the first source/drain epitaxial structures is such that the first source/drain epitaxial structures are in contact with the top surface of the bottom dielectric isolator.

3. The method of claim 1, wherein the bottom dielectric isolator has a thickness in a range from about 50 angstroms to about 70 angstroms.

4. The method of claim 1, wherein after replacing the dummy gate and the sacrificial layer with the gate structure, a bottom surface of the gate structure is higher than a bottom surface of the bottom dielectric isolator.

5. The method of claim 1, wherein forming the fin structure over the bottom dielectric isolator comprises:
forming a first bonding layer over the substrate;
forming a second bonding layer over an epitaxial stack;
bonding the first bonding layer and the second bonding layer to form the bottom dielectric isolator, wherein the epitaxial stack is over the substrate; and
patterning the epitaxial stack to form the fin structure.

6. The method of claim 5, further comprising patterning the bottom dielectric isolator by using the fin structure as an etch mask.

7. The method of claim 1, further comprising forming an isolation structure over the substrate prior to forming the fin structure.

8. A method comprising:
forming a first dielectric layer over a substrate;
forming a second dielectric layer over an epitaxial stack;
bonding the second dielectric layer to the first dielectric layer to form a bottom dielectric isolator, wherein the epitaxial stack is over the substrate and comprises a first channel layer, a sacrificial layer, and a second channel layer from bottom to top; and
forming a complementary field-effect transistor (CFET) over the substrate and the bottom dielectric isolator, wherein the CFET comprises the first channel layer and the second channel layer of the epitaxial stack.

9. The method of claim 8, further comprising:
forming an isolation structure over the substrate prior to forming the first dielectric layer.

10. The method of claim 8, wherein forming the CFET over the substrate comprises:
patterning the epitaxial stack to form a fin structure comprising the first channel layer, the sacrificial layer, and the second channel layer;
patterning the fin structure to expose the bottom dielectric isolator;
forming first source/drain epitaxial structures on opposite sides of the first channel layer and in contact with the first channel layer;
forming second source/drain epitaxial structures on opposite sides of the second channel layer and in contact with the second channel layer; and
replacing the sacrificial layer with a gate structure.

11. The method of claim 10, wherein the gate structure is in contact with the bottom dielectric isolator.

12. The method of claim 10, wherein forming the CFET over the substrate further comprises:
forming a contact etch stop layer (CESL) and an interlayer dielectric (ILD) layer to cover the first source/drain epitaxial structures prior to forming the second source/drain epitaxial structures.

13. The method of claim 12, wherein the CESL is in contact with the bottom dielectric isolator.

14. The method of claim 9, further comprising removing the substrate after forming the CFET, wherein after removing the substrate, a bottom surface of the bottom dielectric isolator is exposed.

15. A device comprising:
a bottom dielectric isolator;
a bottom nanostructure transistor over the bottom dielectric isolator, wherein the bottom nanostructure transistor comprises:
a channel layer;
a gate structure wrapping around the channel layer and in contact with the bottom dielectric isolator; and
a first source/drain epitaxial structure and a second source/drain epitaxial structure connected to the channel layer and directly over the bottom dielectric isolator; and
a top nanostructure transistor over the bottom nanostructure transistor.

16. The device of claim 15, wherein the first source/drain epitaxial structure and the second source/drain epitaxial structure are in contact with the bottom dielectric isolator.

17. The device of claim 15, wherein the bottom dielectric isolator is an oxide layer.

18. The device of claim 15, wherein the bottom dielectric isolator has a thickness in a range from about 50 angstroms to about 70 angstroms.

19. The device of claim 15, further comprising a backside via under and electrically connected to the first source/drain epitaxial structure, wherein the bottom dielectric isolator is in contact with the backside via.

20. The device of claim 15, further comprising a contact etch stop layer covering the first source/drain epitaxial structure and in contact with a sidewall of the bottom dielectric isolator.
